(19) United States
(12) Patent Application Publication
(10) Pub. No.: US 2023/0170297 A1
(43) Pub. Date: Jun. 1, 2023

(54) SEMICONDUCTOR COMPONENT INCLUDING BACK SIDE INPUT/OUTPUT SIGNAL ROUTING

(71) Applicant: IMEC VZW, Leuven (BE)

(72) Inventors: Shih-Hung CHEN, Kessel-Lo (BE); Eric BEYNE, Heverlee (BE); Geert VAN DER PLAS, Leuven (BE)

(21) Appl. No.: 17/991,255

(22) Filed: Nov. 21, 2022

(30) Foreign Application Priority Data
Nov. 26, 2021 (EP) 21210849.2

(51) Int. Cl. H01L 23/522; H01L 27/02; H01L 27/105; H01L 23/492; H01L 23/60; H01L 23/00

(52) U.S. Cl. CPC H01L 23/5226; H01L 23/60; H01L 23/4926; H01L 24/02; H01L 27/105; H01L 27/0255; H01L 27/0259; H01L 27/0292; H01L 2224/02373

(57) ABSTRACT

A semiconductor component, for example an integrated circuit chip, including a semiconductor substrate having active devices at the front side thereof and I/O terminals at the back side of the component, is provided. In one aspect, the terminals are connected to the active devices through TSV connections and buried rails in an area of the substrate that is separate from the area in which the active devices are located. The I/O TSV connections are located in a floating well of the substrate that is separated from the rest of the substrate by a second well formed of material of the opposite conductivity type compared to the material of the floating well. The second well includes at least one contact configured to be coupled to a voltage that is suitable for reverse-biasing the junction between the floating well and the second well. A small capacitance is placed in series with the large parasitic capacitance generated by a thin dielectric liner that isolates the I/O TSVs and I/O rails from the substrate, thereby mitigating the negative effect of the large parasitic capacitance. Additional contacts and conductors can be provided which are configured to create an ESD protection circuit for protecting the I/O TSVs and the I/O rails from electrostatic discharges.

### CROSS-REFERENCE TO RELATED APPLICATIONS

This application claims foreign priority to European Application No. 21210849.2, filed Nov. 26, 2021, which is incorporated by reference herein in its entirety.

### BACKGROUND

### Technological Field

The disclosed technology is related to semiconductor processing, in particular to a semiconductor component, such as an integrated circuit chip, including active devices such as complementary metal-oxide-semiconductor (CMOS) processed transistors at the front side of a semiconductor substrate, and wherein the input/output (I/O) signal routing to and from the active devices takes place via the back side of the substrate.

### Description of the Related Technology

Back side power supply in integrated circuits (ICs) has been part of an ongoing development in semiconductor processing, aimed at enabling increased device density in the front end of line. Higher numbers of active devices (for example, transistors) of ever decreasing device dimensions are placed on a given surface of semiconductor material. This may cause a strain on the design and fabrication of the interconnects between these active devices and the power supply terminals of the IC.

One solution to this problem is to use the introduction of a power delivery network (PDN) on the back side of the semiconductor substrate, combined with the processing of buried power rails (BPR) in the front end of line, and Through Semiconductor Via (TSV) connections which are conductors which run from the front side of the substrate to the back side, connecting the power rails to the back side PDN and hence to power supply terminals also arranged on the back side of the chip. This approach has been described, for example, in European Application Publication No. EP3324436. Processing steps that may be implemented for the back side power supply include thinning the substrate on whose front side the active devices have been produced, to a thickness in the order of 1 micron or less, followed by the etching of nano-sized via openings, filling these openings with a conductive material, and producing interconnect layers on the back side of the thinned substrate. In another solution, the vias are formed prior to substrate thinning (the so-called via-first approach). The via diameters are in the order of nanometers, hence the term “nanoTSVs,” which has been commonly used to describe these front-to-back connections.

The above-cited publication also describes the routing of I/O signals to the back side of the chip, either through isolated portions of the PDN or through an area separate from the PDN. The I/O signals are thereby routed from the active devices at the front through nanoTSV connections to I/O terminals on the back side of the chip.

As nanoTSVs pass through a semiconductor substrate formed of a semiconductor material of a given polarity, the nanoTSVs that transmit I/O signals are required to be electrically isolated from that material. This is realized by providing a dielectric liner around the electrically conductive center of the TSV.

However, the low thickness of this liner and its relatively large surface area can be responsible for the creation of an important parasitic capacitance between the nanoTSV conductor and the surrounding substrate, which can have a negative impact on functional signal transceiving. The parasitic capacitance of a back side I/O interconnect is in fact much larger than that of a front side I/O interconnect. Not only the nanoTSVs as such, but also the ESD protection devices in an external I/O design, can bring significant parasitic capacitance due to large device sizes.

### SUMMARY OF CERTAIN INVENTIVE ASPECTS

The disclosed technology aims to provide a solution to at least some of the above-described problems. These and other aims can be achieved by a semiconductor component in accordance with embodiments of the disclosed technology.

The disclosed technology is related to a semiconductor component, for example an integrated circuit chip, including a semiconductor substrate having active devices at the front side thereof and I/O terminals at the back side of the component. The I/O terminals are connected to the active devices through TSV connections and buried rails in an area of the substrate that is separate from the area in which the active devices are located. According to the disclosed technology, the I/O TSV connections are located in a floating well of the substrate that is separated from the rest of the substrate by a second well formed of material of the opposite conductivity type compared to the material of the floating well. The second well includes at least one contact configured to be coupled to a voltage that is suitable for reverse-biasing the junction between the floating well and the second well. In this way, a small capacitance is placed in series with the large parasitic capacitance generated by a thin dielectric liner that isolates the I/O TSVs and I/O rails from the substrate, thereby mitigating the negative effect of the large parasitic capacitance. According to some embodiments, additional contacts and conductors are provided which are configured to create an ESD (Electrostatic Discharge) protection circuit for protecting the I/O TSVs and the I/O rails, and thereby the I/O terminals from electrostatic discharges.

The disclosed technology is in particular related to a semiconductor component including a semiconductor substrate having a front side and a back side, and including a first area and a second area not overlapping the first area, the areas extending from the front side of the substrate to the back side through the complete thickness of the substrate, wherein the component includes:
a device layer at the front side of the substrate, including a plurality of active devices located in the first area, wherein the active devices are configured to receive input signals and to send output signals, the input and output signals being referred to hereafter as “I/O signals”;
a plurality of buried interconnect rails at least partially buried in the substrate, at the front side thereof, and located in the second area, the buried rails being referred to hereafter as “I/O rails”;
a plurality of through substrate via (TSV) connections located in the second area, hereafter referred to as “I/O TSVs,” passing through the substrate from the buried rails to the back side of the substrate, each I/O TSV and each I/O rail being isolated from the substrate by a dielectric liner;
a front side redistribution layer on the device layer, configured to route the I/O signals between the active devices in the first area and the buried I/O rails in the second area;
input/output terminals at the back side of the component;
a back side redistribution layer at the back side of the substrate configured to route the I/O signals between the I/O terminals on the back side of the component and the back end of the I/O TSVs; and
a plurality of power supply terminals (Vss, V_{DD}) and conductors connected thereto, configured to supply power to the active devices, the power supply terminals being coupled to either a reference voltage Vss or a power voltage V_{DD}, and wherein:
the plurality of I/O TSVs and the plurality of I/O rails are located in a first well of the substrate, the first well being formed of semiconductor material of a first conductivity type, the first well extending from the front side of the substrate to the back side of the substrate, through the complete thickness of the substrate,
the first well is a floating well, that is, a well that is not provided with contacts for applying a bias voltage to the first well,
the substrate includes a second well in the second area, the second well extending from the front side of the substrate to the back side of the substrate through the complete thickness of the substrate, wherein the second well separates the first well from the rest of the substrate, the second well being of a second conductivity type opposite the first conductivity type, so that a junction is formed between the first well and the second well, and
the second well includes at least one contact, configured to enable the application of a bias voltage to the second well, so as to reverse bias at least part of the junction between the first well and the second well.

According to an embodiment, the component further includes buried power rails and power TSV connections in the first area, coupled to Vss and V_{DD} terminals at the back side of the component and coupled to the active devices in the device layer at the front side of the substrate for supplying power thereto. The contact of the second well may be coupled to V_{DD}.

The component of the disclosed technology may further include additional contacts, junctions, and conductors which implement an ESD protection circuit for protecting the I/O rails and the I/O TSVs from ESD pulses.

According to an embodiment including an ESD circuit:
the substrate is formed of semiconductor material of the first conductivity type,
the contact of the second well is coupled to V_{DD} and is hereafter referred to as the first contact, the first contact including a region of the second conductivity type,
the substrate includes a second contact coupled to Vss, the second contact including a region of the first conductivity type, located adjacent the second well,
the second well includes a third contact opposite the first contact, meaning at the other side of the substrate compared to the first contact, the third contact including a region of the first conductivity type,
the substrate includes a fourth contact opposite the second contact, the fourth contact including a region of the second conductivity type,
the third and fourth contacts are coupled to the I/O rails, so that the ESD circuit is a double diode circuit formed by two diodes formed respectively by at least part of the junction between the substrate and the region of the fourth contact and by at least part of the junction between the second well and the region of the third contact.

A double-diode circuit is an ESD protection circuit of an electronic component including one or more Vss terminals, one or more V_{DD} terminals, and one or more I/O terminals, the circuit including at least one set of two diodes as shown in FIG. 5, that is, two diodes coupled in series between Vss and V_{DD}, and wherein the conductor that connects the diodes is coupled to the I/O terminals.

According to a further embodiment:
the second well further includes a fifth contact, including a region of the first conductivity type, and located adjacent the fourth contact and at the same side of the substrate as the fourth contact, wherein the fifth contact is coupled to the I/O rails, so that the ESD circuit additionally includes a bipolar transistor formed by:
at least part of the junction between the region of the fifth contact and the second well, and
at least part of the junction between the floating well and the second well.

According to another embodiment including an ESD circuit:
the substrate is formed of semiconductor material of the first conductivity type,
the contact of the second well is coupled to V_{DD} and is hereafter referred to as the first contact, the first contact including a region of the second conductivity type,
the substrate includes a second contact coupled to Vss, the second contact including a region of the first conductivity type, located adjacent the second well,
the second well includes a third contact opposite the first contact, the third contact including a region of the first conductivity type,
the second well includes a fourth contact also opposite the first contact and adjacent the third contact, the fourth contact including a region of the second conductivity type,
the second well includes a fifth contact on the same side of the substrate as the third and fourth contacts but on the opposite side of the floating well, the fifth contact including a region of the second conductivity type,
the substrate includes a sixth contact adjacent the fifth contact and opposite the second contact, the sixth contact including a region of the second conductivity type,
the substrate includes a seventh contact adjacent the sixth contact and also opposite the second contact, the seventh contact including a region of the first conductivity type,
the third contact and the sixth contact are coupled to the I/O rails,
the fourth contact and the fifth contact are coupled to V_{DD}, and
the seventh contact is coupled to Vss,
so that the ESD circuit is a double diode circuit including:
a first set of two diodes formed respectively by a first portion of the junction between the substrate and the region of the sixth contact and by a first portion of the junction between the second well and the region of the third contact,
a second set of two diodes formed respectively by a second portion of the junction between the substrate and the region of the sixth contact and by a second portion of the junction between the second well and the region of the third contact,
a bipolar transistor formed by:
   at least part of the junction between the region of the sixth contact and the substrate,
   at least part of the junction between the floating well and the second well.

According to an embodiment, one or more of the additional contacts include regions which form guard rings around the floating well.

The disclosed technology is also related to a component according to any of the above embodiments, wherein the substrate is a p or n doped silicon substrate.

The disclosed technology is also related to an integrated circuit chip according to any of the above embodiments.

### BRIEF DESCRIPTION OF THE DRAWINGS

FIGS. 1A-1C show top section views and a front section view through a portion of an integrated circuit chip in accordance with a first embodiment of the disclosed technology, including a floating p-well surrounded by an n-well.

FIGS. 2A and 2B show a top section view and a front section view through a portion of an integrated circuit chip in accordance with a second embodiment of the disclosed technology, including a floating p-well surrounded by an n-well.

FIGS. 3A and 3B show a top section view and a front section view through a portion of an integrated circuit chip in accordance with the first embodiment of the disclosed technology, but wherein the n-well includes a guard ring.

FIGS. 4A and 4B show a top section view and a front section view through a portion of an integrated circuit chip in accordance with an embodiment of the disclosed technology further including an ESD protection.

FIG. 5 illustrates the equivalent circuit of the ESD protection of FIG. 4.

FIGS. 6A and 6B show a further example of an integrated circuit chip according to the disclosed technology, including another embodiment of an ESD protection circuit.

FIG. 7 illustrates the equivalent circuit of the ESD protection implemented in the embodiment of FIGS. 6A and 6B.

FIGS. 8A and 8B show a further example of an integrated circuit chip according to the disclosed technology, including another embodiment of an ESD protection circuit. FIG. 8C shows an enlarged detail of the front section shown in FIG. 8A.

FIG. 9 illustrates the equivalent circuit of the ESD protection implemented in the embodiment of FIGS. 8A, 8B, and 8C.

FIGS. 10A and 10B illustrate an embodiment wherein the same ESD protection is implemented as in FIGS. 8A, 8B, and 8C, but wherein the various p+ and n+ regions at the front side are all implemented as guard rings.

FIGS. 11A and 11B illustrate an embodiment according to the disclosed technology having supply power terminals at the front side and I/O terminals at the back side.

### DETAILED DESCRIPTION OF CERTAIN ILLUSTRATIVE EMBODIMENTS

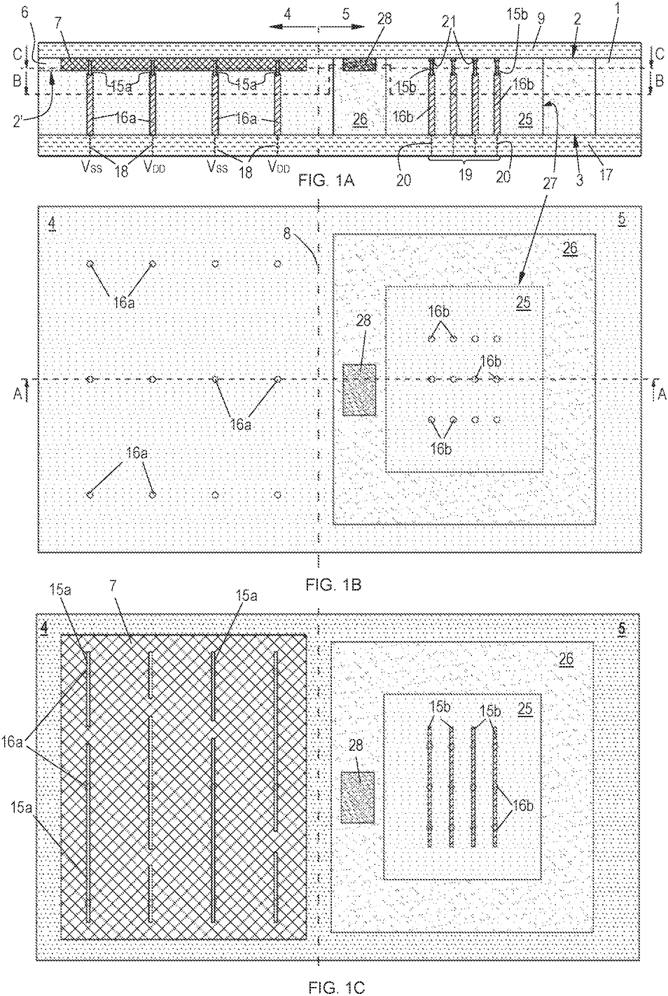

With reference to FIGS. 1A to 1C, a first embodiment of the disclosed technology is hereafter described. All cited materials and statements in relation to the dimensions of features shown in the drawings are merely given by way of example and not as limitations of the scope of the disclosed technology. The figures represent schematic simplifications of an actual IC and are aimed at explaining the characteristic elements of the disclosed technology. The figures are not intended to represent actual devices in terms of the relative position and dimensions of the various elements that are represented.

As seen in FIGS. 1A to 1C, the IC includes a semiconductor substrate 1, which may be a monocrystalline Si substrate of a thickness between 200 nm and 1 micrometer, having a front side and a back side, respectively indicated by the numerals 2 and 3. However, the terms “front side” and “back side” are not to be interpreted as unique planes of the substrate, but rather as more generic indicators of the distinction between the two planar sides of the substrate.

Throughout the description of disclosed technology, the terms “front side” and “back side” are used in relation to the substrate as well as to the component (for example, the IC) as a whole. For example, when it is stated that a layer is located “at the front side” of the substrate, this may refer to a layer that is on top of the substrate, possibly with other layers between the front surface of the substrate and the layer in question, or it may refer to a top layer of the substrate as such. Likewise, “terminals” located “at the back of the component” may include terminals directly on the back surface of the component or fully or partially embedded in the back surface. A dividing line 8 is drawn between a first area 4 and second area 5 of the substrate 1. The areas 4 and 5 are non-overlapping and extend from the front side 2 to the back side 3 of the substrate 1, through the full thickness of the substrate 1. At the front side of the substrate 1, the IC includes a device layer 6, including a plurality of active devices. The device layer 6 is a top layer of the substrate 1 as such, from the dotted line 2′ upwards.

In some ICs, the devices in layer 6 can include a large number of nano-scaled transistors such as finFETs or nano-sheet based transistors, processed according to a given layout. Without showing details of the devices as such, the rectangle 7 in FIGS. 1A and 1C indicates a plurality of such devices located at the front side of the substrate 1, and in the first area 4. The second area 5 does not include active devices. The active device layer 6 further includes electrical conductors (not shown) coupled to the active devices. These may include via connections to the source or drain and to the gate of finFET transistors. These connections are coupled to a front side redistribution layer 9 on top of the device layer 6, which is a layer including multiple levels of conductors running parallel to the substrate 1, with conductors of adjacent levels being interconnected by vertical via connections. These features can be suitably implemented are not described in more detail. The device layer 6, and in particular the rectangle 7, largely corresponds to the so-called front end of line (FEOL) portion of an IC, while the front side redistribution layer 9 largely corresponds to the back end of line portion (BEOL), with the multiple interconnect levels known as M1, M2, etc. The FEOL is often understood to include a first level of conductors directly coupled to the devices, the M0 (Metal zero) level. In the present context, this M0level may be regarded either as part of the device layer 6 or as part of the front side redistribution layer 9.

With reference again to FIGS. 1A-1C, the IC further includes interconnect rails 15a and 15b which are buried in the substrate 1. These rails are elongate structures which may, for example, be a few tens of nanometers in width, while extending longitudinally in the direction perpendicular to the frontal section view in FIG. 1A. As indicated in the introduction, buried rails are features enabling the supply of power to the active devices from the back side of the chip and/or to route I/O signals through the substrate 1.

In the first area 4 of the IC illustrated in FIG. 1A, a first set of buried rails 15a is formed, which will hereafter be referred to as “power rails.” An example of a possible pattern of the power rails 15a is illustrated in the section view along the plane C-C in FIG. 1C. Details of the active devices are not shown in this view. As in the front section view of FIG. 1A, the active devices are understood to be positioned in the rectangle 7. The power rails 15a extend through dielectric isolation areas (not shown) between adjacent active semiconductor portions, for example between groups of Si fins, and hence into the substrate 1. At the front side, the power rails 15a are connected to the active devices via local interconnects (not shown) which may include via connections and conductors in the M0 level. At the back side, the power rails 15a are connected to nanoTSVs 16a, hereafter referred to as “power TSVs,” which run through the full thickness of the substrate 1, to a back side redistribution layer 17. The position of the power TSVs 16a is also indicated in the plane section views of FIGS. 1B and 1C.

The back side redistribution layer 17 is similar to the front side redistribution layer 9, that is, it is a multilevel interconnect structure including several layers of conductors running parallel to the substrate 1 and interconnected by via connections. The back side redistribution layer 17 together with the power TSVs 16a are part of the back side power delivery network PDN, configured to deliver power to the active devices in the first area (and other “first areas” of the IC). Power supply voltage levels are conventionally noted as a power voltage V_{DD} supplied with respect to a reference (usually ground) voltage Vss. Power terminals are provided at the back of the IC which are configured to be coupled to an external power source. In FIG. 1A these terminals are indicated by the notations of V_{DD} and Vss next to vertical dotted lines 18 passing from the power TSVs 16a to the back side of the IC. These dotted lines 18 do not represent actual conductors, but they are symbolic representations of the conductive paths, through conductors and vias of the back side redistribution layer 17, between the power TSVs 16a and the V_{DD} and Vss terminals at the back side of the IC.

The second area 5 is now described in more detail. This second area 5 includes an array of nanoTSVs 16b, hereafter referred to as “I/O TSVs,” dedicated to the transmission of I/O signals between the front side and the back side of the substrate 1. To this aim, the IC further includes a number of I/O terminals 19 on its back side which are connected to the I/O TSVs 16b through conductors of the back side redistribution layer 17, symbolized by the dotted lines 20. The I/O TSVs 16b are connected at their front side to a further set of buried rails 15b, hereafter referred to as “I/O rails,” which are coupled to the front side redistribution layer 9 through conductors symbolized by the connections 21 which may be via connections or a combination of vias and conductors in the M0level.

Through the front side redistribution layer 9, input and output signals are routed to and from the active devices in the first area 4. The I/O TSVs 16b and the I/O rails 15b and the connections 21 are isolated from the substrate 1 by dielectric liners, which are not shown in detail in the drawings because of the drawing scale but can be suitably implemented. This is a thin layer of a few nm thick, often formed of SiO₂, deposited on the sidewalls of via openings and trenches prior to filling these openings and trenches with an electrically conductive material such as Cu or Ru.

The elements described so far are known as such, that is, I/O interconnects to the back side through “I/O TSVs” and “I/O buried rails” situated in an area that is remote from the active devices. As stated in the introduction, these configurations can suffer from the high level of parasitic capacitance generated by the I/O TSVs and the I/O buried rails.

This problem can be solved in the configuration shown in FIGS. 1A-1C, by the fact that the I/O TSVs 16b and I/O rails 15b are situated in a “floating well” 25. This is a first well region 25 of the substrate 1, that is, region of doped semiconductor material, that extends from the front side of the substrate to the back side, across the full thickness of the substrate 1. The first well 25 consists of semiconductor material of a first conductivity type (p or n), and is separated from the rest of the substrate by a second well region 26 of the opposite conductivity type (n or p) extending also from the front side of the substrate to the back side across the full thickness of the substrate. For the sake of explaining the disclosed technology, the floating well 25 in the embodiment of FIGS. 1A-1C will be described hereafter as a p-well 25, that is surrounded by an n-well 26. Also, the substrate 1 is to be regarded in the context of the following explanation as a p-doped substrate, that is, the substrate 1 is p-doped everywhere except where n-doped regions are created. The inverse configuration with p and n reversed is, however, also possible.

The p-well 25 is “floating” in the sense that it is not connected to an external voltage, that is, it does not include a contact configured to be connected to such an external voltage. In particular, the p-well 25 is isolated from the Vss and V_{DD} power terminals. On the other hand, the surrounding n-well 26 is configured to be biased, that is, placed at a given voltage that can be set at a particular level, in order to cause the depletion of at least part of the p-n junction 27 between the floating well 25 and the surrounding n-well 26. In the embodiment shown, this is realized by producing a contact to the n-well 26 at the front side thereof, in the form of a heavily n-doped region 28 (hereafter referred to as “n+ contact”) that is connected to the lowest level of the front side redistribution layer 9. The connection may take place by a via connection (not shown) between the contact 28 and the lowest level. The representation of a “contact” as a heavily doped region is again a simplification of the reality in order to present merely the concept of the disclosed technology. It will be understood that in reality the contact includes the heavily doped region as well as a contact pad on the heavily doped region, the pad formed of metal or another electrically conductive material.

Through the front side redistribution layer 9 and the n+ contact 28, the n-well 26 may then be placed at a required voltage, which could, for example, be the supply voltage V_{DD}, routed to the n+ contact 28 from a V_{DD} terminal (one of the locations labelled “V_{DD}” in FIG. 1A) at the back, through the power delivery network, the power TSVs 16a and power rails 15a, and the front side redistribution layer 9. Alternatively, the bias voltage may be another positive voltage, generated by one of the active devices and routed to the n+ contact 28 through the front side redistribution layer 9 to thereby reverse-bias at least part of the p-n junction 27.

The effect of the reverse-biased p-n junction 27 is to place a small capacitance in series with the large parasitic capacitance generated by the liners of the I/O TSVs 16b and the I/O rails 15b, resulting in a drastic reduction of the overall parasitic capacitance influencing the I/O signal transceiving through the I/O TSVs 16b and rails 15b.

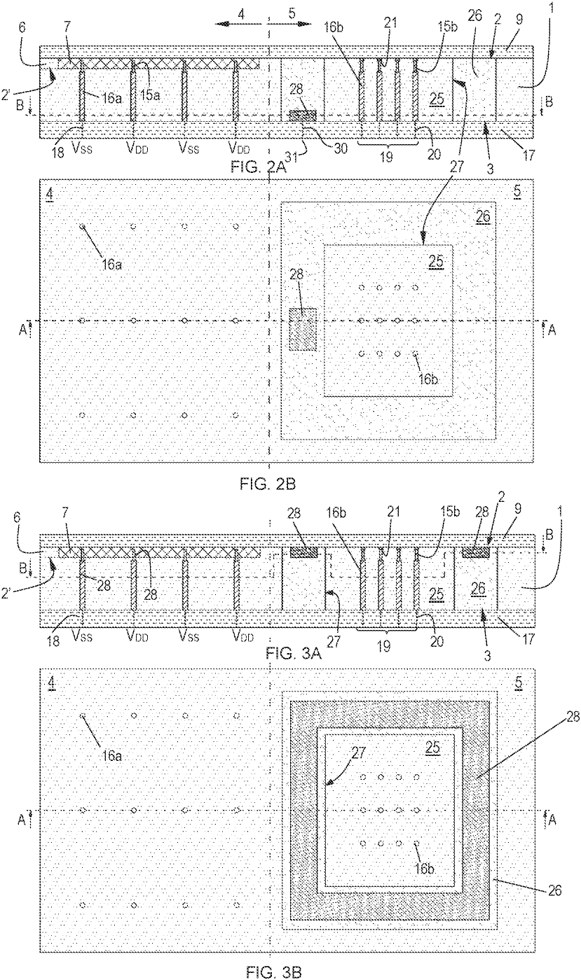

In an alternative embodiment that is equivalent to the embodiment of FIGS. 1A-1C, the bias voltage could be applied from the back side of the IC, as is illustrated in FIGS. 2A and 2B. The n+ contact 28 is now provided at the back surface of the substrate and coupled through conductors of the back side redistribution layer 17, symbolized by the dotted line 30, to a terminal 31 at the back of the IC. Terminal 31 could, for example, be coupled to the supply voltage V_{DD}.

The embodiment shown in FIGS. 3A and 3B has the same effect as the embodiment of FIGS. 1A-1C, 2A, and 2B, but now the n+ region 28 is formed as a guard ring running along the complete upper surface of the n-well 26. This embodiment ensures that the depletion of the p-n junction 27 extends around the full circumference of the floating p-well 25.

According to some embodiments of the disclosed technology, the means for creating a depleted p-n junction in series with the parasitic capacitance of the I/O rails 15b and I/O TSVs 16b is combined with additional contacts and connections which form an ESD protection circuit for the protection of the I/O terminals 19 and thereby the active devices in the first area 4 from electrostatic discharges. A first embodiment of this type is illustrated in FIGS. 4A and 4B. The n+ contact 28 is again a heavily n-doped region at the back side of the substrate (as in the embodiment of FIGS. 2A-2B), and connected to a V_{DD} terminal at the back side through conductors of the back side redistribution layer 17 symbolized by the dotted line 30. Adjacent to the n-well 26, the second area 5 of the substrate 1 now includes a heavily p-doped region (hereafter referred to as p+ contact) 35 at the back side of the p-substrate 1, and a connection to this p+ contact 35 through conductors of the back side redistribution layer 17, symbolized by the dotted line 36, which are coupled to a Vss terminal at the back side of the IC. At the front side of the substrate 1, a p+ contact 37 is provided in the n-well 26, opposite the contact 28, and an n+ contact 38 is provided in the p-substrate 1 adjacent the n-well 26 and opposite the contact 35. Both these additional p+ and n+ contacts 37 and 38 are connected through conductors of the front side redistribution layer 9 symbolized by the dotted lines 40 to all of the I/O rails 15b and I/O TSVs 16b. The doping type of regions 37 and 38 (p and n) is opposite to the doping type of the substrate parts 26 and 1 (n and p) in which they are embedded, thereby creating p-n junctions 50 and 49.

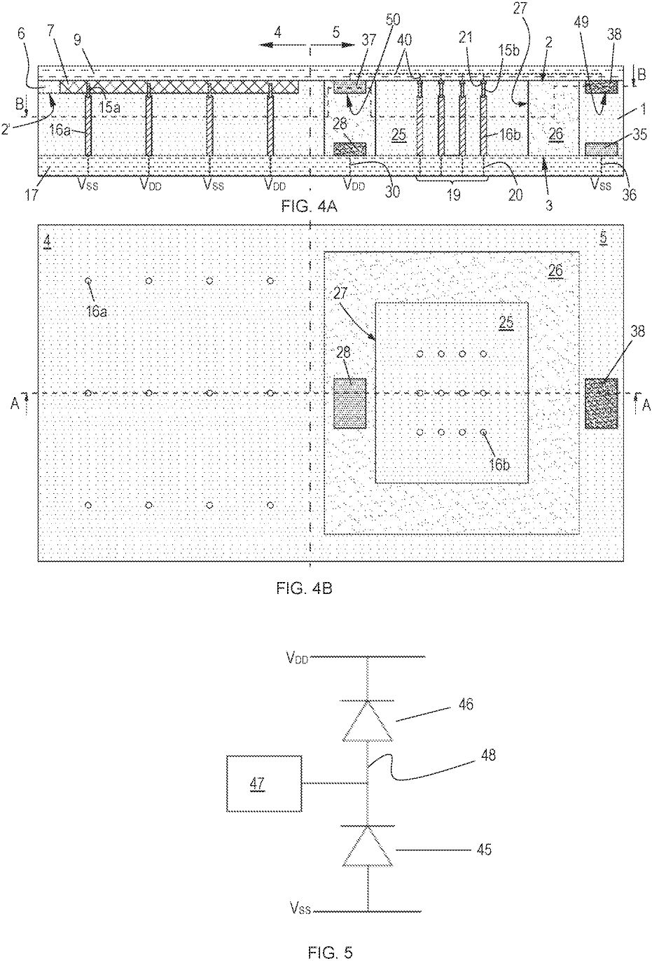

In this way, a double diode ESD protection circuit is obtained, as depicted in FIG. 5, including two diodes 45 and 46 arranged in series between Vss and V_{DD}, and with the I/O interconnects 47 coupled to the connection 48 between the first and second diode. In the configuration of FIGS. 4A and 4B, the junctions 49 and 50 respectively represent the diodes 45 and 46 of the ESD circuit. Only a portion of the junctions may actually contribute to the diode formation, depending on the exact geometry of the doped regions with respect to each other. It can therefore be stated that the diodes are formed by “at least part of the junctions.” The connection to Vss is embodied by the p+ contact 35 and the path 36, while the connection to V_{DD} is embodied by the n+ contact 28 and the path 30. In this configuration, the junction 27 is reverse biased by the n-well 26 that is coupled to V_{DD} thereby decreasing the parasitic capacitance, while at the same time, the I/O interconnects (terminals 19, I/O TSVs 16b and I/O rails 15b) are protected from ESD pulses.

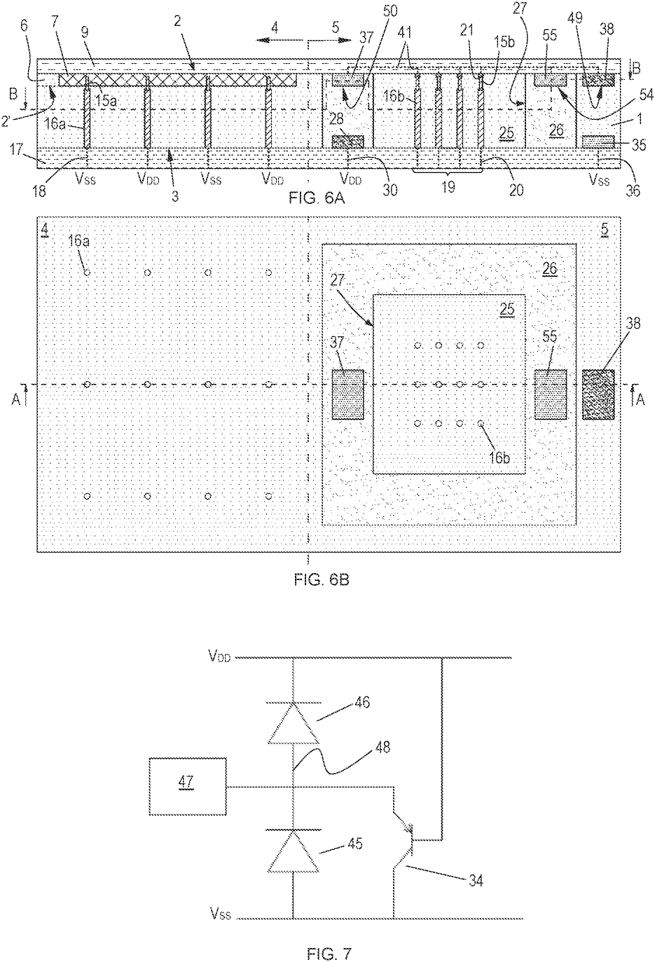

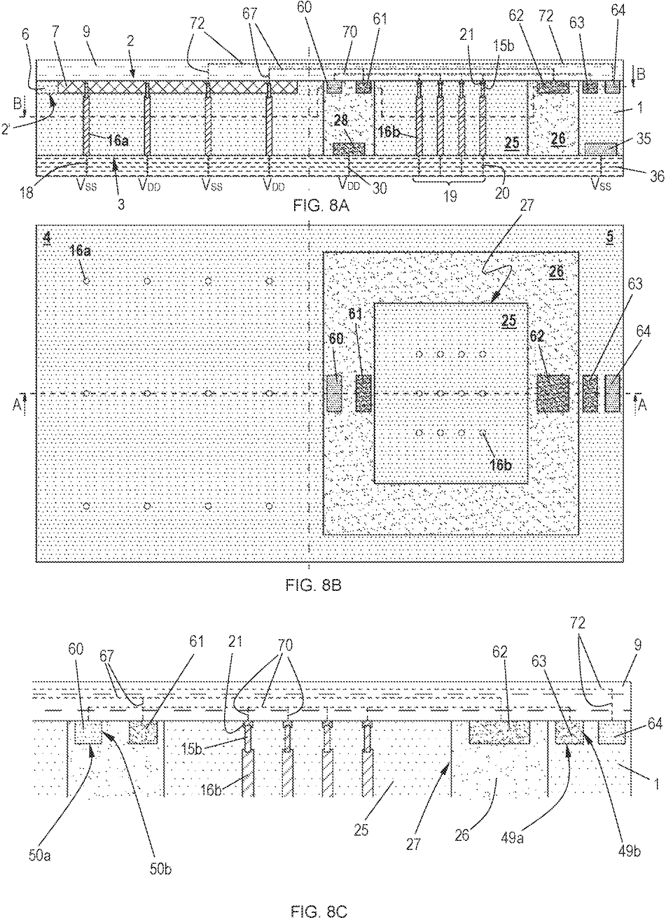

The integration of an ESD protection together with the decreased parasitic capacitance can be realized in various ways other than the configuration shown in FIGS. 4A and 4B, as illustrated by a number of further embodiments. In the embodiment of FIGS. 6A and 6B, an additional p+ contact 55 is implemented at the front side of the substrate 1, adjacent the n+ contact 38 and on the opposite side of the p-n junction 27 relative to the n+ contact 38. The additional p+ contact 55 is connected through conductors in the front side redistribution layer 9 symbolized by the dotted lines 41 to the I/O rails 15b and I/O TSVs 16b, that is, this additional p+ region 55 is at the same voltage as the p+ contact 37 and the n+ contact 38. An additional p-n junction 54 is thereby created. The double diode circuit is therefore realized in the same manner as in the previous embodiment, but in addition thereto and as shown in the equivalent circuit in FIG. 7, a parallel ESD discharge path is created between Vss and V_{DD} by a bipolar pnp transistor 34 embodied by the junction 27 and at least a portion of junction 54.

Another embodiment is shown in FIGS. 8A to 8C, with FIG. 8C showing an enlarged detail of the front section shown in FIG. 8A. The n+ contact 28 and the p+ contact 35 are again present at the back side of the substrate 1, respectively coupled to V_{DD} and Vss. At the front side of the substrate, an n+ contact 60 and a p+ contact 61 are now provided in the n-well 26 on one side thereof and opposite the n+ contact 28, while another n+ contact 62 is provided also in the n-well 26 and at the front side of the substrate, but on the other side of the floating p-well 25 In the substrate adjacent to the n-well 26, another n+ contact 63 and a p+ contact 64 are provided. The n+ contacts 60 and 62 are both coupled to V_{DD}. The path that connects these front side n+ contacts 60 and 62 to a V_{DD} terminal at the back of the IC includes conductors of the front side redistribution layer 9, symbolized by the dotted lines 67. The p+ contact 61 and the n+ contact 63 are coupled to the I/O rails 15b and I/O TSVs 16b through conductors of the front side redistribution layer symbolized by the dotted lines 70. The p+ contact 64 is coupled to Vss. The path that connects this front side p+ contact 64 to a Vss terminal at the back of the IC includes conductors of the front side redistribution layer 9 symbolized by the dotted lines 72.

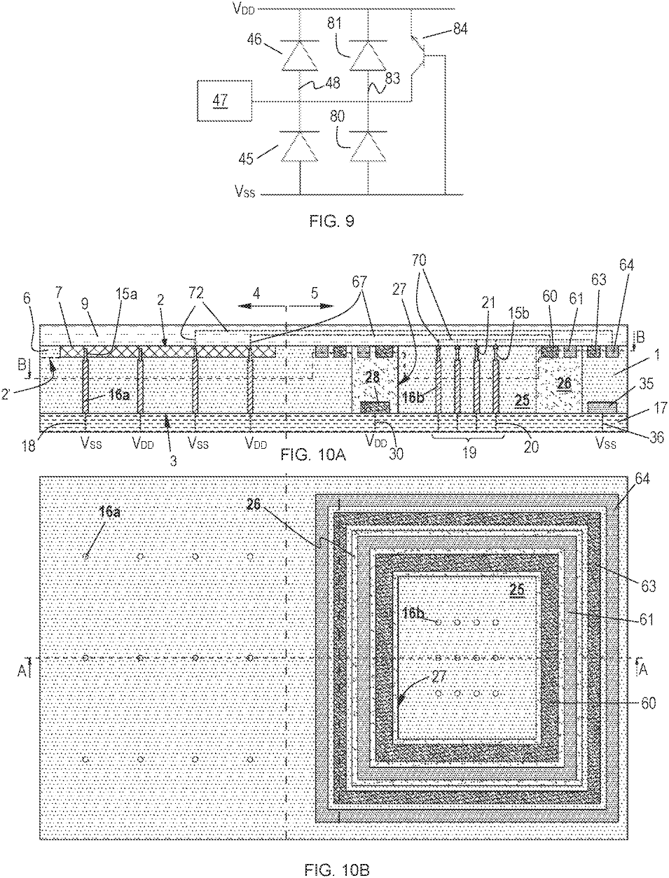

The equivalent circuit of the configuration of FIGS. 8A-8B is shown in FIG. 9. The first diodes 45 and 46 are now embodied by portions 49a and 50a of the junctions 49 and 50 (see FIG. 8C). Two additional parallel diodes 80 and 81 coupled by connection 83 are embodied by the respective portions 49b and 50b of the junctions 49 and 50, while a parallel bipolar npn transistor 84 is embodied by the junctions 27 and a portion of junction 49.

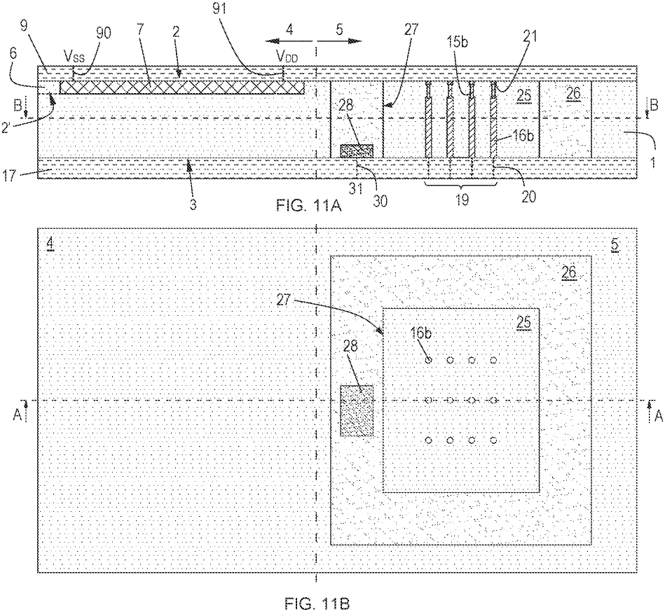

FIGS. 10A and 10B show another embodiment, wherein the same ESD protection is implemented as in FIGS. 8A-B and 9, but wherein the various p+ and n+ regions of the various contacts at the front side of the substrate 1 form guard rings extending fully around the floating p-well 25. Regions 60 and 62 in FIGS. 8A-8B are now part of the same guard ring 60. It is also possible to combine guard rings for some of the contacts with local regions for other contacts.

The embodiments shown in FIGS. 4A to 10B are mere examples of how an ESD circuit can be implemented together with the floating well configured to decrease the parasitic capacitance. Based on these examples, it will be understood other alternatives can be implemented and are therefore all included in the scope of the disclosed technology.

In the embodiments of FIGS. 4A to 10B, the n+ contact 28 and the p+ contact 35 are formed at the back side of the substrate, while the other contacts 37, 38 etc., are formed at the front side. The same ESD circuits can be obtained by reversing these positions, that is, contacts 28 and 35 at the front side and the other contacts at the back side of the substrate. The routing of the various I/O signals and supply currents will be different, taking place through the front side redistribution layer 9 instead of the through the back side redistribution layer 17 or vice versa, but the eventual circuits will be the same.

The disclosed technology is not limited to components having supply terminals for Vss and V_{DD} on the back side, but it is also applicable to components having these supply terminals on the front side, while having I/O terminals on the back side. Such an embodiment is shown in FIGS. 11A and 11B, which is equivalent to FIGS. 1A-1C apart from the location of the V_{DD} and Vss terminals. These terminals are now at the front side and are configured to deliver power to the active devices in the first area 4 through conductors of the front side redistribution layer 9 symbolized by the dotted lines 90 and 91. Apart from this, the routing of the I/O signals through the back side and through I/O TSVs 16b located in a floating p-well 25 is the same as in the embodiment of FIGS. 1A-1C.

Methods that are applicable for producing a component according to the disclosed technology can be suitably implemented and are not described here in detail. Method steps can include dopant implant steps for creating the floating well 25 and/or the second well 26, as well as the doped regions of the various contacts 28, 35, etc. Suitable lithographic masks are to be applied in order to limit the dopant implants to the required areas.

While the disclosed technology has been illustrated and described in detail in the drawings and foregoing description, such illustration and description are to be considered illustrative or exemplary and not restrictive. Other variations to the disclosed embodiments can be understood and effected by those skilled in the art in practicing the disclosed technology. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

What is claimed is:

1. A semiconductor component comprising a semiconductor substrate having a front side and a back side, and comprising a first area and a second area not overlapping the first area, the areas extending from the front side of the substrate to the back side through a complete thickness of the substrate, the semiconductor component comprising:
a device layer at the front side of the substrate, comprising a plurality of active devices located in the first area, wherein the active devices are configured to receive input signals and to send output signals (I/O signals);
a plurality of buried interconnect rails (I/O rails) at least partially buried in the substrate, at the front side thereof, and located in the second area;
a plurality of through substrate via (TSV) connections (I/O TSVs) located in the second area, passing through the substrate from the I/O rails to the back side of the substrate, each I/O TSV and each I/O rail being isolated from the substrate by a dielectric liner;
a front side redistribution layer on the device layer, configured to route the I/O signals between the active devices in the first area and the I/O rails in the second area;
input/output terminals (I/O terminals) at the back side of the component;
a back side redistribution layer at the back side of the substrate configured to route the I/O signals between the I/O terminals on the back side of the component and a back end of the I/O TSVs; and
a plurality of power supply terminals (V_{SS}, V_{DD}) and conductors connected thereto, configured to supply power to the active devices, the power supply terminals being coupled to either a reference voltage Vss or a power voltage V_{DD}, wherein:
the plurality of I/O TSVs and the plurality of I/O rails are located in a first well of the substrate, the first well being formed of semiconductor material of a first conductivity type, the first well extending from the front side of the substrate to the back side of the substrate, through the complete thickness of the substrate,
the first well is a floating well that is not provided with contacts for applying a bias voltage to the first well,
the substrate comprises a second well in the second area, the second well extending from the front side of the substrate to the back side of the substrate through the complete thickness of the substrate, wherein the second well separates the first well from the rest of the substrate, the second well being of a second conductivity type opposite the first conductivity type, so that a junction is formed between the first well and the second well, and
the second well includes at least one contact, configured to enable an application of a bias voltage to the second well, so as to reverse bias at least part of the junction between the first well and the second well.

2. The component according to claim 1, further comprising buried power rails and power TSV connections in the first area, coupled to Vss and V_{DD} terminals at the back side of the component and coupled to the active devices in the device layer at the front side of the substrate for supplying power thereto.

3. The component according to claim 1, wherein the at least one contact of the second well is coupled to V_{DD}.

4. The component according to claim 1, further comprising additional contacts, junctions, and conductors which implement an ESD protection circuit for protecting the I/O rails and the I/O TSVs from ESD pulses.

5. The component according to claim 4, wherein:
the substrate is formed of semiconductor material of the first conductivity type,
the at least one contact of the second well comprises a first contact coupled to V_{DD} and comprising a region of the second conductivity type;
the substrate comprises a second contact coupled to Vss, wherein the second contact comprises a region of the first conductivity type, located adjacent the second well;
the second well comprises a third contact opposite the first contact, at the other side of the substrate compared to the first contact, the third contact comprising a region of the first conductivity type;
the substrate comprises a fourth contact opposite the second contact, the fourth contact comprising a region of the second conductivity type; and
the third and fourth contacts are coupled to the I/O rails, so that the ESD circuit is a double diode circuit formed by two diodes formed respectively by at least part of the junction between the substrate and the region of the fourth contact and by at least part of the junction between the second well and the region of the third contact.

6. The component according to claim 5, wherein the second well further comprises a fifth contact, comprising a region of the first conductivity type, and located adjacent the fourth contact and at the same side of the substrate as the fourth contact, wherein the fifth contact is coupled to the I/O rails, so that the ESD circuit additionally comprises a bipolar transistor formed by:
at least part of the junction between the region of the fifth contact and the second well, and
at least part of the junction between the floating well and the second well.

7. The component according to claim 4, wherein:
the substrate is formed of semiconductor material of the first conductivity type,
the at least one contact of the second well comprises a first contact coupled to V_{DD} and comprises a region of the second conductivity type,
the substrate comprises a second contact coupled to Vss, the second contact comprising a region of the first conductivity type, located adjacent the second well,
the second well comprises a third contact opposite the first contact, the third contact comprising a region of the first conductivity type,
the second well comprises a fourth contact also opposite the first contact and adjacent the third contact, the fourth contact comprising a region of the second conductivity type,
the second well comprises a fifth contact on the same side of the substrate as the third and fourth contacts but on the opposite side of the floating well, the fifth contact comprising a region of the second conductivity type,
the substrate comprises a sixth contact adjacent the fifth contact and opposite the second contact, the sixth contact comprising a region of the second conductivity type,
the substrate comprises a seventh contact adjacent the sixth contact and also opposite the second contact, the seventh contact comprising a region of the first conductivity type,
the third contact and the sixth contact are coupled to the I/O rails,
the fourth contact and the fifth contact are coupled to V_{DD}, and
the seventh contact is coupled to V_{SS},
so that the ESD circuit is a double diode circuit comprising:
a first set of two diodes formed respectively by a first portion of the junction between the substrate and the region of the sixth contact and by a first portion of the junction between the second well and the region of the third contact,
a second set of two diodes formed respectively by a second portion of the junction between the substrate and the region of the sixth contact and by a second portion of the junction between the second well and the region of the third contact, and
a bipolar transistor formed by:
at least part of the junction between the region of the sixth contact and the substrate, and
at least part of the junction between the floating well and the second well.

8. The component according to claim 4, wherein one or more of the additional contacts comprise regions which form guard rings around the floating well.

9. The component according to claim 1, wherein the substrate is a p or n doped silicon substrate.

10. The component according to claim 1, wherein the component is an integrated circuit chip.
